(19) United States
(12) Patent Application Publication
(10) Pub. No.: US 2002/0043526 A1
(43) Pub. Date: Apr. 18, 2002

(54) System and method for efficiently implementing a thermal processing chamber

(76) Inventor: Alex Blanter, Berkeley, CA (US)

Correspondence Address: Gregory J. Koerner, SIMON & KOERNER LLP, Suite B, 10052 Pasadena Avenue, Cupertino, CA, 95014, US

(21) Appl. No.: 09/947,962

(22) Filed: Sep. 6, 2001

Related U.S. Application Data
(60) Provisional application No. 60/241,082, filed on Oct. 16, 2000.

(51) Int. Cl. C23C 16/00; F27B 5/14

(52) U.S. Cl. 219/390; 219/411; 118/725; 118/728

(57) ABSTRACT

A system and method for efficiently implementing a thermal processing chamber may preferably include a bottom insert positioned within a bottom cover and a top insert positioned within a top cover. The bottom insert and the top insert may preferably be formed of one or more thermally-insulating materials that possess optimal heat-resistive characteristics. The foregoing bottom insert and top insert are positionable in a closed position of the thermal processing chamber to form an interior insulated region within the thermal processing chamber. A heater formed of one or more heater materials with minimal thermal capacity properties may then be positioned within the interior insulated region of the thermal processing chamber to generate heat energy during a heating cycle. The heat energy is thereby substantially confined within the interior insulated region of the thermal processing chamber during the heating cycle. A plurality of gasflow holes may preferably be configured to propagate a gasflow through the interior insulated region of the thermal processing chamber to thereby remove the heat energy during a cooling cycle that follows the foregoing heating cycle. The thermal processing chamber is therefore configured for thermally insulating the interior insulated region to facilitate rapidly performing heating cycles and cooling cycles to thereby improve production speeds and semiconductor product quality characteristics while simultaneously consuming a minimal amount of heat energy.

### CROSS-REFERENCE TO RELATED APPLICATIONS

This application relates to, and claims priority in, U.S. Provisional Patent Application Ser. No. 60/241,082, entitled “System And Method For Implementing A High-Efficiency Thermal Processing Chamber,” filed on Oct. 16, 2000, which is hereby incorporated by reference.

### BACKGROUND SECTION

1. Field of the Invention

This invention relates generally to techniques for thermal processing, and relates more particularly to a system and method for efficiently implementing a thermal processing chamber.

2. Description of the Background Art

Implementing efficient methods for performing manufacturing processes is a significant consideration for designers and manufacturers of contemporary electronic devices. However, developing efficient systems for performing manufacturing processes may create substantial challenges for system designers. For example, enhanced demands for increased system functionality and performance may require additional system capabilities and additional resources. An increase in necessary capabilities or resources may also result in a corresponding detrimental economic impact due to increased economic costs and operational inefficiencies. Furthermore, the capability to perform various advanced manufacturing processes may provide additional benefits to a system user, but may also place increased demands on the control and management of various system components.

One significant type of manufacturing process is the production of semiconductor electronic devices such as integrated circuits. In many semiconductor manufacturing processes it is required to rapidly heat a wafer of semiconductor material to a predetermined temperature, and then cool the wafer after a particular process step has been completed. For example, consider rapid thermal processing (RTP) which is used for many steps in semiconductor manufacturing. During RTP, a wafer is typically heated to a process temperature with various different types of heat sources such as tungsten halogen lamps, resistive heaters, and other similar means for heating.

Heating rates typically approach 250 degrees centigrade per second, and cooling rates may be as high as 100 degrees centigrade per second. RTP chambers are typically made from stainless steel (cold-wall water-cooled chambers), or from quartz (hot-wall chambers). These chamber walls are heated and cooled together with the wafer during a processing cycle. RTP systems are precise, but are also complicated and expensive. In another technique, a batch of wafers is heated in a batch furnace. The batch furnace typically includes a quartz tube surrounded by graphite heaters. Large quantities of wafers are typically processed simultaneously by the batch furnace. Batches of wafers inside the batch furnace are slowly heated to a predetermined temperature. Slow cooldown of the wafers is necessary in order to keep reasonable temperature uniformity within the wafers. The foregoing batch furnaces are typically inaccurate and slow.

From the foregoing comments, it is apparent that developing new techniques for efficiently performing manufacturing processes is a matter of concern for related electronic technologies. Therefore, for all the foregoing reasons, developing efficient and effective systems for performing manufacturing processes remains a significant consideration for designers, manufacturers, and users of contemporary electronic devices.

### SUMMARY

In accordance with the present invention, a system and method are disclosed for efficiently implementing a thermal processing chamber. In one embodiment, the foregoing chamber may preferably include, but is not limited to, a bottom cover, a top cover, a bottom insert, a top insert, a heater, a plurality of lift pins, a wafer, a plurality of gasflow holes, and an interior region. In alternate embodiments, the chamber may readily be implemented using various components and configurations in addition to, or instead of, those elements and configurations that are discussed in conjunction with the foregoing embodiment.

In certain embodiments, the bottom cover may preferably include an approximately cylindrical interior vertical wall that connects along a lower edge to an approximately circular interior horizontal wall. The bottom insert may preferably include an approximately cylindrical external vertical wall that connects along a lower edge to an approximately circular external horizontal wall. The bottom insert may preferably be sized to fit within the bottom cover, with the interior vertical wall of the bottom cover being adjacent to the exterior vertical wall of the bottom insert, and the interior horizontal wall of the bottom cover being adjacent to the exterior horizontal wall of the bottom insert.

The bottom insert may preferably also include an approximately cylindrical internal vertical wall that connects along a lower edge to an approximately circular internal horizontal wall. In certain embodiments, an approximately circular heater may preferably be positioned adjacent and parallel to the internal horizontal wall of the bottom insert.

In certain embodiments, the top cover may preferably include an approximately cylindrical interior vertical wall that connects along an upper edge to an approximately circular interior horizontal wall. The top insert may preferably include an approximately cylindrical external vertical wall that connects along an upper edge to an approximately circular external horizontal wall.

The top insert may preferably be sized to fit within the top cover, with the interior vertical wall of the top cover being adjacent to the exterior vertical wall of the top insert, and the interior horizontal wall of the top cover being adjacent to the exterior horizontal wall of the top insert. The top insert may preferably also include an approximately cylindrical internal vertical wall that connects along an upper edge to an approximately circular internal horizontal wall.

In accordance with the present invention, the top cover (with the top insert attached) may then be positioned in contact with the bottom cover (with the bottom insert attached) to thereby advantageously create an approximately cylindrical insulated interior region within the chamber. In certain embodiments, a lower edge of the approximately cylindrical vertical wall of the top cover may preferably be positioned adjacent to, and in contact with, an upper edge of the approximately cylindrical vertical wall of the bottom cover. Similarly, a lower edge of the approximately cylindrical vertical wall of the top insert may preferably be positioned adjacent to, and in contact with, an upper edge of the approximately cylindrical vertical wall of the bottom insert.

A wafer of semiconductor material (or any other appropriate type of target material) may then be positioned adjacent and parallel to the heater on a plurality of lift pins. In certain embodiments, the wafer may be positioned with the lift pins in a lower position for more effective heating near the heater. The wafer may also be positioned with the lift pins in a higher position for more effective cooling away from the heater. In certain embodiments, the interior region of the chamber may be effectively cooled by propagating a gasflow of one or more inert gases through a series of gasflow holes.

In accordance with the present invention, the foregoing thermal processing chamber is therefore advantageously configured for thermally insulating said interior region to facilitate rapidly performing said heating cycle and said cooling cycle to thereby improve production speeds and semiconductor product quality characteristics while simultaneously consuming a minimal amount of heat energy. The present invention thus provides an improved system and method for efficiently implementing a thermal processing chamber.

### BRIEF DESCRIPTION OF THE DRAWINGS

FIG. 1 is an elevation view of a thermal processing chamber, in accordance with one embodiment of the present invention;

FIG. 2 is a vertical cross-sectional view for one embodiment of the thermal processing chamber of FIG. 1, in accordance with the present invention;

FIG. 3 shows several views for one embodiment of the bottom cover of FIG. 2, in accordance with the present invention;

FIG. 4 shows several views for one embodiment of the bottom insert of FIG. 2, in accordance with the present invention;

FIG. 5 shows several views for one embodiment of the top insert of FIG. 2, in accordance with the present invention;

FIG. 6 shows several views for one embodiment of the top cover of FIG. 2, in accordance with the present invention;

FIG. 7 is plan view for one embodiment of the heater of FIG. 2, in accordance with the present invention;

FIG. 8 is a horizontal cross-sectional view of the chamber of FIG. 1, in accordance with one embodiment of the present invention;

FIG. 9 is a graph showing thermal capacity characteristics of the bottom insert and the top insert of FIG. 2, in accordance with one embodiment of the present invention;

FIG. 10 is a graph showing thermal conductivity characteristics of the bottom insert and the top insert of FIG. 2, in accordance with one embodiment of the present invention; and

FIG. 11 is a flowchart of method steps for efficiently implementing a thermal processing chamber, in accordance with one embodiment of the present invention.

### DETAILED DESCRIPTION

The present invention relates to an improvement in thermal processing techniques. The following description is presented to enable one of ordinary skill in the art to make and use the invention and is provided in the context of a patent application and its requirements. Various modifications to the disclosed embodiments will be readily apparent to those skilled in the art, and the generic principles herein may be applied to other embodiments. Thus, the present invention is not intended to be limited to the embodiments shown, but is to be accorded the widest scope consistent with the principles and features described herein.

The present invention comprises a system and method for efficiently implementing a thermal processing chamber, and may preferably include a bottom insert positioned within a bottom cover and a top insert positioned within a top cover. The bottom insert and the top insert may preferably be formed of one or more thermally-insulating materials that possess optimal heat-resistive characteristics.

The foregoing bottom insert and top insert are preferably positionable in a closed position of the thermal processing chamber to thereby form an interior insulated region within the thermal processing chamber. A heater formed of one or more heater materials with minimal thermal capacity characteristics may then be positioned within the interior insulated region of the thermal processing chamber to generate heat energy during a heating cycle. The foregoing heat energy is thereby substantially confined within the interior insulated region of the thermal processing chamber during the heating cycle.

A plurality of gasflow holes may preferably be configured to propagate a gasflow through the interior insulated region of the thermal processing chamber to thereby remove the heat energy during a cooling cycle that follows the foregoing heating cycle. The thermal processing chamber is therefore configured for thermally insulating the interior insulated region to facilitate rapidly performing heating cycles and cooling cycles to thereby improve production speeds and semiconductor product quality characteristics while simultaneously consuming a minimal amount of heat energy from the heater.

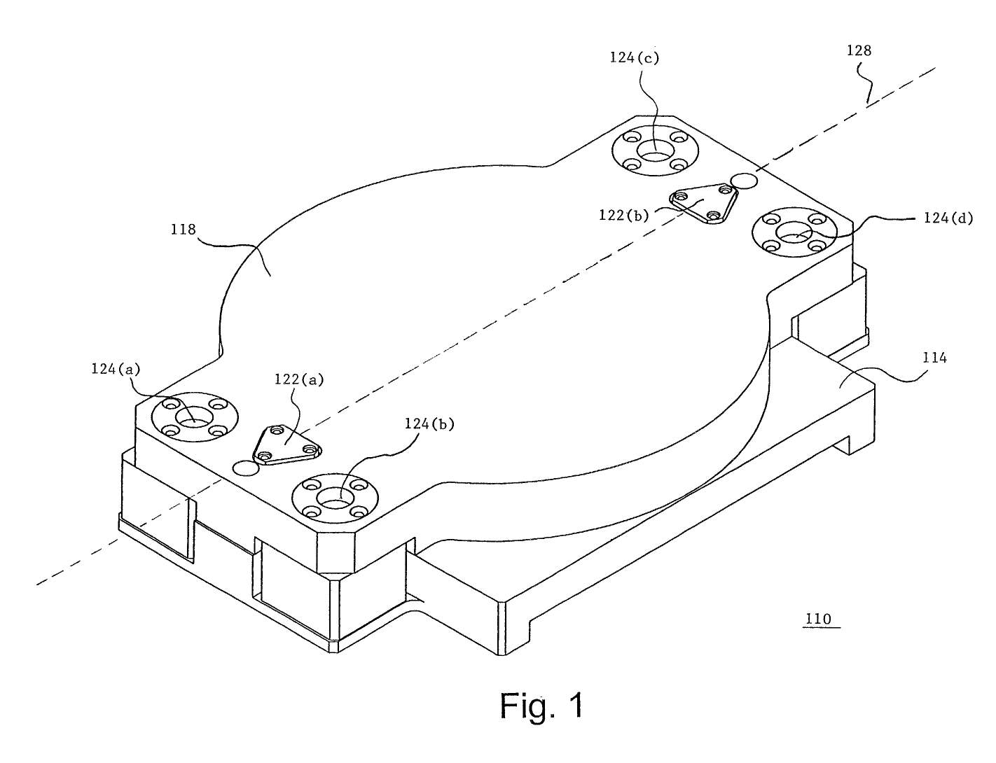

Referring now to FIG. 1, an elevation view of a thermal processing chamber is shown, in accordance with one embodiment of the present invention. In the FIG. 1 embodiment, chamber 110 may preferably include, but is not limited to, a bottom cover 114 and a top cover 118. In alternate embodiments, chamber 110 may readily be implemented using various elements and configurations in addition to, or instead of, those elements and configurations discussed in conjunction with the FIG. 1 embodiment.

For example, in certain embodiments, chamber 110 may be implemented utilizing various other physical proportions and shapes. In addition, the FIG. 1 embodiment is disclosed and discussed in the context of thermal processing of semiconductor wafer material, however in various alternate embodiments, the principles of the present invention may readily be utilized to perform appropriate thermal processing procedures for various other applications and uses.

In accordance with the present invention, chamber 110 advantageously provides a complete thermal semiconductor processing environment that is characterized by high thermal uniformity and high heating and cooling rates. Thermal uniformity operates to ensure defect-free processing of semiconductor wafers. High heating and cooling rates operate to reduce thermal exposure of the wafer, which in turn improves the quality of manufactured semiconductor devices. Chamber 110 achieves these qualities by combining materials and design elements that have very low thermal capacities and exceptional thermal insulating properties. As a result, semiconductor wafers are isolated from the outside environment and are more efficiently heated and cooled.

Semiconductor processing chambers such as chamber 110 may be described by various parameters which include chamber throughput (the number of wafers that a chamber can process in one hour), and the cost of chamber operation. The number of wafers that a chamber can process in one hour is defined by a combination of the processing time and overhead time (such as wafer placement, alignment and removal). The processing time of chamber 110 may preferably consist of a combined heating time and cooling time.

In the FIG. 1 embodiment, in order to heat a semiconductor wafer, chamber 110 may utilize an actively controlled heater and highly insulating materials for the chamber walls, which operate to reduce requirements of the chamber heater, and allow for significant reduction in heating times. In the FIG. 1 embodiment, effectively cooling semiconductor wafers may be achieved by flowing large quantities of nitrogen or other appropriate gases through chamber 110. A cooling rate (which defines the cooling time) is limited by the ability of the nitrogen gas flow to remove heat energy from the semiconductor wafer and other heated components such as the heater and chamber walls. In accordance with the present invention, the reduction in thermal capacity of the heater and chamber walls advantageously improves the cooling rate.

In accordance with the present invention, chamber 110 may preferably include one or more pneumatic cylinders 124 that may be attached to a pressurize air source (not shown). In the FIG. 1 embodiment, chamber 110 preferably includes four pneumatic air cylinders 124(a), 124(b), 124(c), and 124(d) that may preferably be spaced around chamber 110 in a manner that connects to both bottom cover 114 and top cover 118.

The FIG. 1 embodiment, chamber 110 may also include one or more guide bearings 122 that may preferably be spaced around chamber 10 in a manner that connects to both bottom cover 114 and top cover 118. In the FIG. 1 embodiment, chamber 110 preferably includes two guide bearings 126(a) and 126(b). The foregoing pressurized air source may inject pressurized air into pneumatic cylinders 124 for causing pneumatic cylinders 124 to expand.

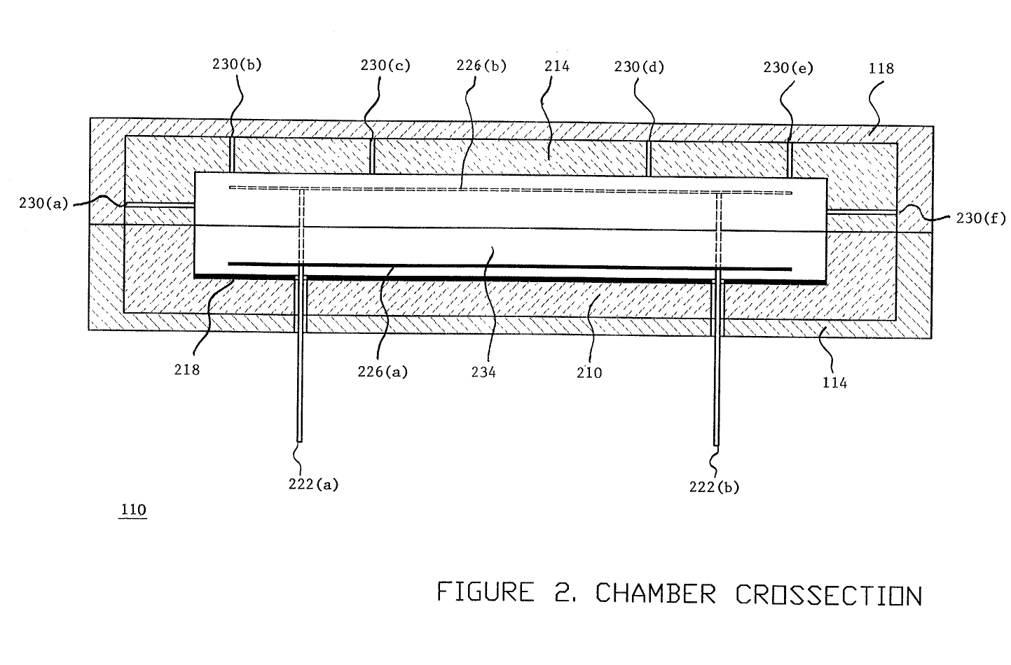

As pneumatic cylinders 124 expand, top cover 118 may preferably ride on guide bearings 124 to effectively separate from bottom cover 114 into an opened position. Similarly, the pressurized air may be released from pneumatic cylinders 124 to allow top cover 118 to resume a closed position against bottom cover 114. Chamber 110 may thus be efficiently opened and closed for convenient insertion and removal of semiconductor wafers, and to facilitate cooling cycles in chamber 110. The configuration and utilization of chamber 110 is further discussed below in conjunction with FIGS. 2 through 11.

Referring now to FIG. 2, a vertical cross-sectional view for one embodiment of the FIG. 1 chamber 110 is shown, in accordance with the present invention. The cross-sectional view of the FIG. 2 embodiment is presented with approximate reference to axis 128 of the FIG. 1 chamber 110. In the FIG. 2 embodiment, chamber 110 may preferably include, but is not limited to, a bottom cover 114, a top cover 118, a bottom insert 210, a top insert 214, a heater 218, a plurality of lift pins 222, a wafer 226, a plurality of gasflow holes 230, and an interior region 234. In alternate embodiments, chamber 110 may readily be implemented using various components and configurations in addition to, or instead of, those elements and configurations discussed in conjunction with the FIG. 2 embodiment.

In the FIG. 2 embodiment, bottom cover 114 may preferably include an approximately cylindrical interior vertical wall that connects along a lower edge to an approximately circular interior horizontal wall. Bottom insert 210 may preferably include an approximately cylindrical external vertical wall that connects along a lower edge to an approximately circular external horizontal wall. Bottom insert 210 may preferably be sized to fit within bottom cover 114 with the interior vertical wall of bottom cover 114 being adjacent to the exterior vertical wall of bottom insert 210, and the interior horizontal wall of bottom cover 114 being adjacent to the exterior horizontal wall of bottom insert 210.

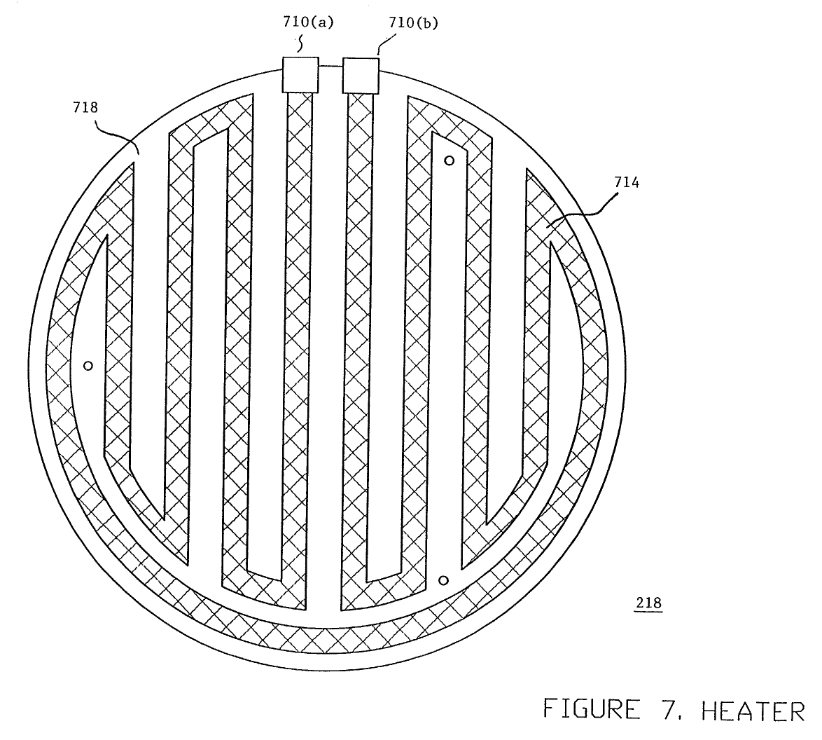

Bottom insert 210 may preferably also include an approximately cylindrical internal vertical wall that connects along a lower edge to an approximately circular internal horizontal wall. In the FIG. 2 embodiment, an approximately circular heater 218 may preferably be positioned adjacent and parallel to the internal horizontal wall of bottom insert 210. Heater 218 is further discussed below in conjunction with FIG. 7.

In the FIG. 2 embodiment, top cover 118 may preferably include an approximately cylindrical interior vertical wall that connects along an upper edge to an approximately circular interior horizontal wall. Top insert 214 may preferably include an approximately cylindrical external vertical wall that connects along an upper edge to an approximately circular external horizontal wall. Top insert 210 may preferably be sized to fit within top cover 118 with the interior vertical wall of top cover 118 being adjacent to the exterior vertical wall of top insert 214, and the interior horizontal wall of top cover 118 being adjacent to the exterior horizontal wall of top insert 214.

Top insert 214 may preferably also include an approximately cylindrical internal vertical wall that connects along an upper edge to an approximately circular internal horizontal wall. In the FIG. 2 embodiment, top insert 214 may be attached to top cover 118 using any appropriate means, such as machine screws or rivets. Similarly, bottom insert 210 may be attached to bottom cover 114 using any appropriate means, such as machine screws or rivets.

In accordance with the FIG. 2 embodiment, top cover 118 (with top insert 214 attached) may then be positioned in contact with bottom cover 114 (with bottom insert 210 attached) to thereby advantageously create an approximately cylindrical insulated interior region 234 within chamber 110. In the FIG. 2 embodiment a lower edge of the approximately cylindrical vertical wall of top cover 118 may preferably be positioned adjacent to, and in contact with, an upper edge of the approximately cylindrical vertical wall of bottom cover 114. Similarly, a lower edge of the approximately cylindrical vertical wall of top insert 214 may preferably be positioned adjacent to, and in contact with, an upper edge of the approximately cylindrical vertical wall of bottom insert 210.

In the FIG. 2 embodiment, a wafer 226 of semiconductor material (or any other appropriate type of target material) may be positioned adjacent and parallel to heater 218 on a plurality of lift pins 222. In the FIG. 2 embodiment, chamber 110 may preferably include moveable lift pin 222(a) and moveable lift pin 222(b). However, in alternate embodiments, chamber 110 may utilize lift pins 222 of any number or shape. For example, in certain embodiments, lift pins 222 may be stationary and not moveable. In the FIG. 2 embodiment, a wafer 226(a) may be positioned with lift pins 222 in a lower position for more effective heating near heater 218. A wafer 226(b) may also be positioned with lift pins 222 in a higher position for more effective cooling away from heater 218

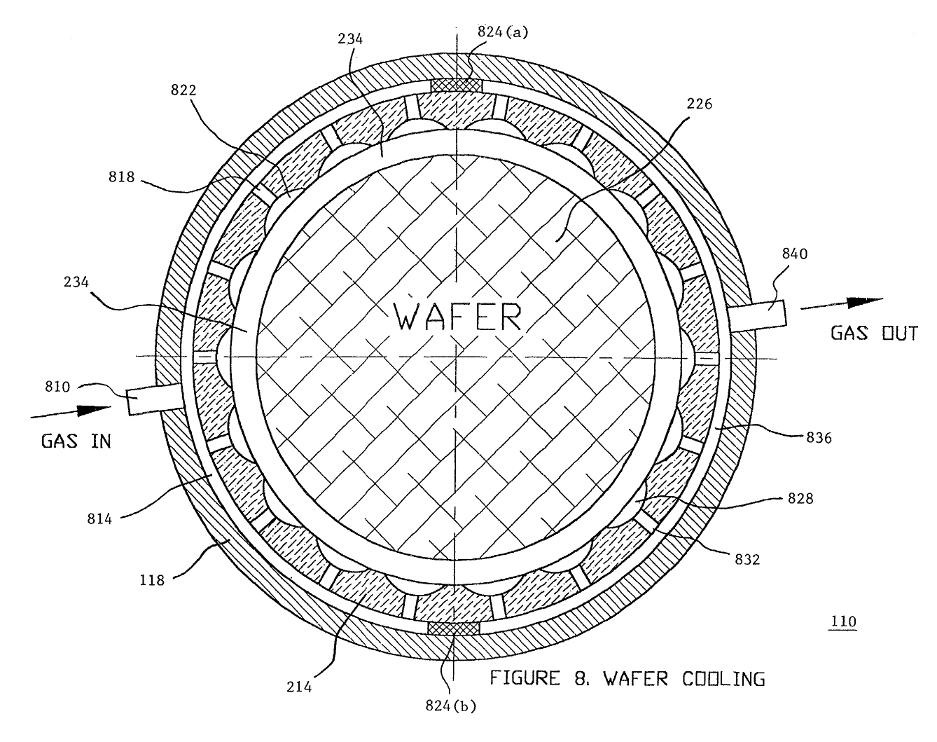

In the FIG. 2 embodiment, the interior region 234 of chamber 110 may be effectively cooled by providing a flow of relatively cool gas through a series of gasflow holes 230. In the FIG. 2 embodiment, the interior region 234 of chamber 110 may be provided with a cooling gasflow through gasflow holes 230(a), 230(b), 230(c), 230(d), 230(e), and 230(f). One embodiment for implementing a gasflow cooling procedure is further discussed below in conjunction with FIG. 8.

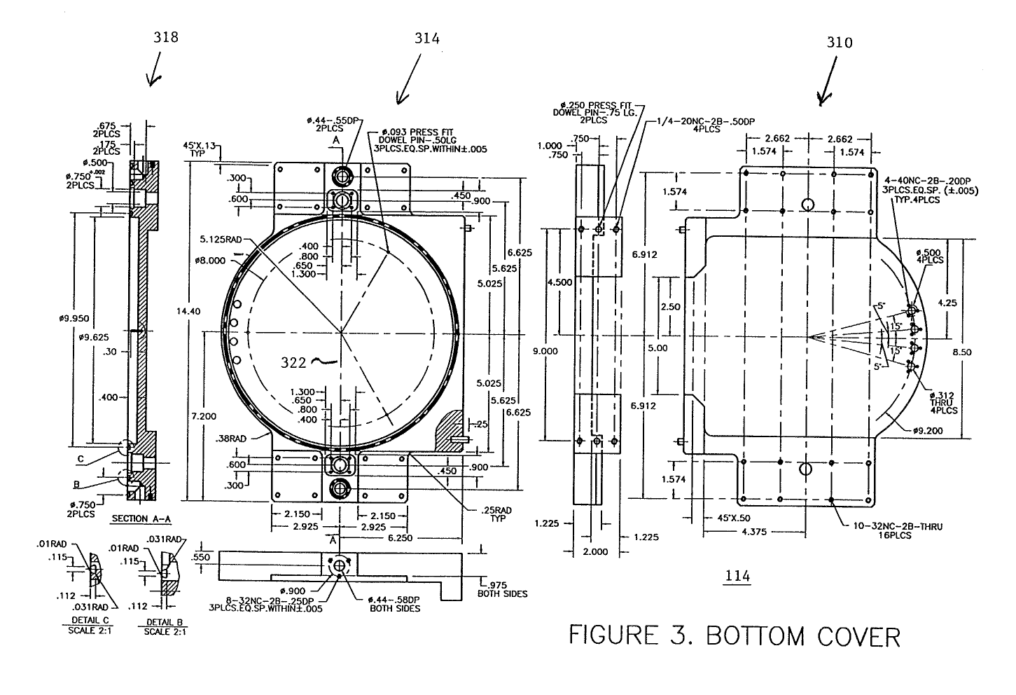

Referring now to FIG. 3, several views for one embodiment of the bottom cover 114 are shown, in accordance with the present invention. In the FIG. 3 drawings, measurements are presented in inches unless the drawings indicate to the contrary. In alternate embodiments, bottom cover 114 may readily include various other elements and configurations in addition to, or instead of, those elements and configurations discussed in conjunction with the FIG. 3 embodiment.

In the FIG. 3 embodiment, view 310 illustrates an exterior plan view of bottom cover 114. View 314 of the FIG. 3 embodiment shows an interior plan view of bottom cover 114 with two pneumatic cylinders and a guide bearing show on both the top and the bottom areas of bottom cover 114. On the left side of view 314, four holes are shown for routing electrical power to heater 218. View 318 shows a cross-sectional view of bottom cover 114 taken along vertical axis 322 of view 314. View 318 also shows an internal diameter of bottom cover 114 (that is sized to receive bottom insert 210) as being equal to 9.625 inches.

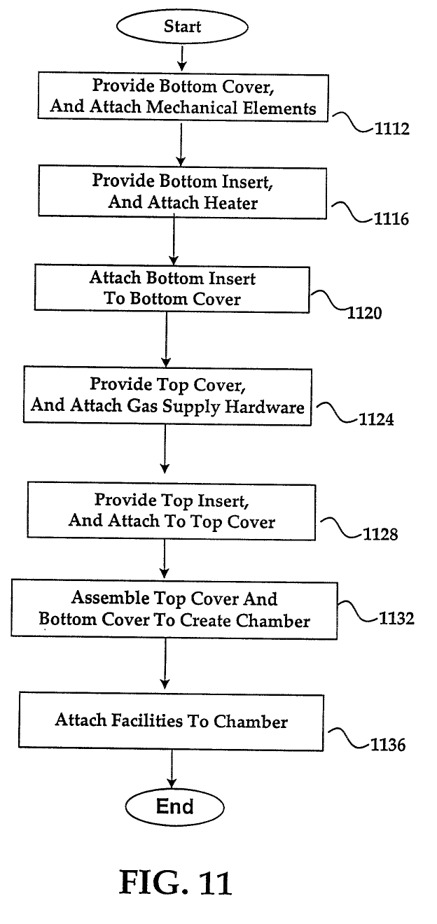

In the FIG. 3 embodiment, bottom cover 114 may be made of any appropriate material that provides suitable structural support for other elements of chamber 110. For example, in certain embodiments, bottom cover 114 may be formed of nickel-plated aluminum. The implementation of chamber 110 using bottom cover 114 is further discussed below in conjunction with FIG. 11.

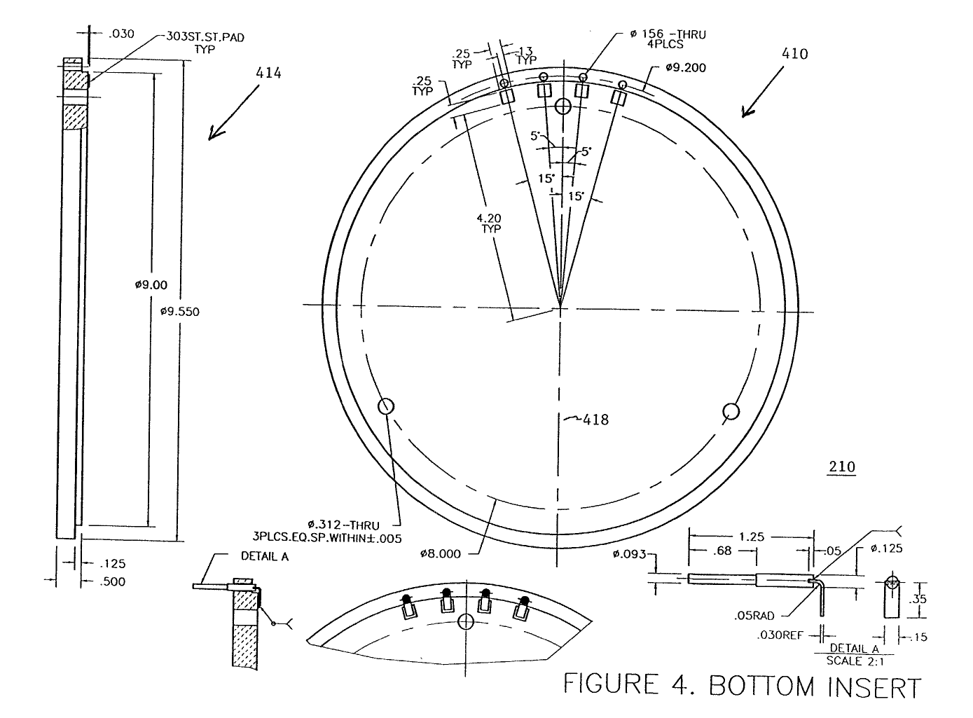

Referring now to FIG. 4, several views for one embodiment of the FIG. 2 bottom insert 210 is shown, in accordance with the present invention. In the FIG. 4 drawings, measurements are presented in inches unless the drawings indicate to the contrary. In alternate embodiments, bottom insert 210 may readily include various other elements and configurations in addition to, or instead of, those elements and configurations discussed in conjunction with the FIG. 4 embodiment.

In the FIG. 4 embodiment, view 410 illustrates an interior plan view of bottom insert 210 with four holes for routing electrical power to heater 218, which may preferably be mounted to bottom insert 210 using any appropriate means. View 414 shows a cross-sectional view of bottom insert 210 taken along vertical axis 418 of view 410. View 414 also shows an external diameter of bottom insert 210 (that is sized to fit into bottom cover 114) as being equal to 9.550 inches.

In the FIG. 4 embodiment, bottom insert 210 may be made of any appropriate material that provides a high degree of thermal insulation for an interior region 234 (FIG. 2) of chamber 110. In the FIG. 4 embodiment, bottom insert 210 may preferably be formed of an alumina enhanced thermal barrier material from a related group of materials known as AETB. Specifically, in the FIG. 4 embodiment, chamber 110 may preferably be formed of AETB-8, which is a low-density (8 pounds per cubic foot) composite tile that is made from small diameter (1-3 microns) silica and alumina fibers and larger (8 microns) aluminoborosilicate fibers. In alternate embodiments, bottom insert 210 may be made from various other highly thermal-resistive materials, such as AETB-16, alumina or fused silica. The implementation of chamber 110 using bottom insert 210 is further discussed below in conjunction with FIG. 11.

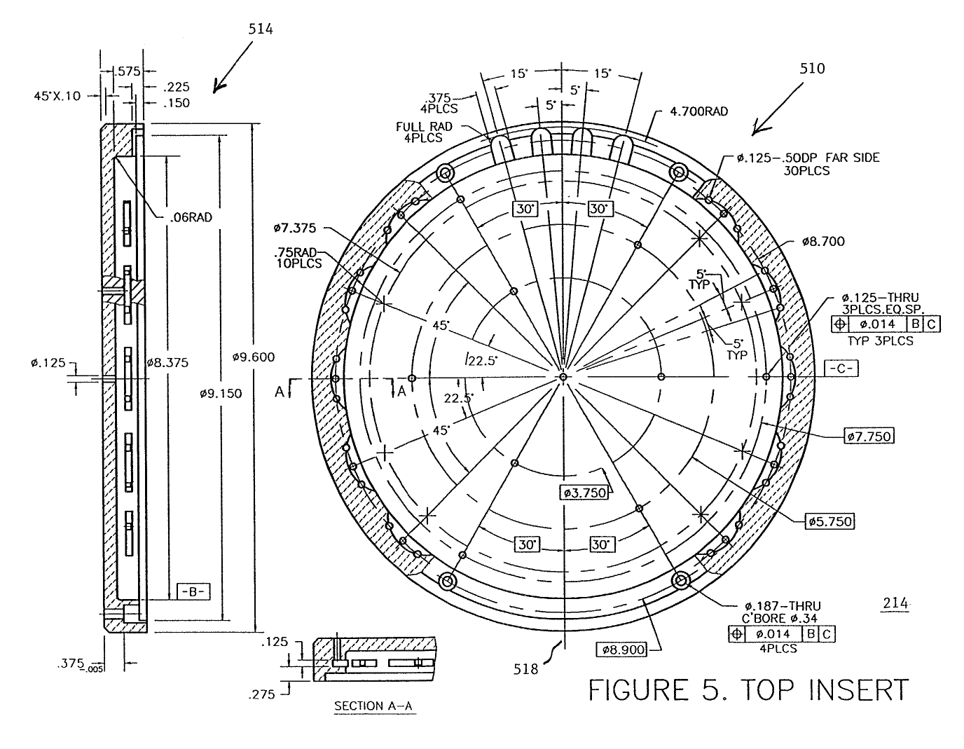

Referring now to FIG. 5, several views for one embodiment of the FIG. 2 top insert 214 are shown, in accordance with the present invention. In the FIG. 5 drawings, measurements are presented in inches unless the drawings indicate to the contrary. In alternate embodiments, top insert 214 may readily be implemented using various elements and configurations in addition to, or instead of, those elements and configurations discussed in conjunction with the FIG. 5 embodiment.

In the FIG. 5 embodiment, view 510 illustrates an interior plan view of top insert 214 with an arrangement of gasflow holes and gasflow slots. Dissipating heat from interior region 234 of chamber 110 using an arrangement of gasflow holes and gasflow slots is further discussed below in conjunction with FIG. 8. In the FIG. 5 embodiment, view 514 shows a cross-sectional view of top insert 214 taken along vertical axis 518 of view 510, including the foregoing arrangement of gasflow holes and gasflow slots. View 514 also shows an external diameter of top insert 214 (that is sized to fit into top cover 118) as being equal to 9.600 inches.

In the FIG. 5 embodiment, top insert 214 may be made of any appropriate material that provides a high degree of thermal insulation for an interior region 234 (FIG. 2) of chamber 110. In the FIG. 5 embodiment, top insert 214 may preferably be formed of an alumina enhanced thermal barrier material from a related group of materials known as AETB. Specifically, in the FIG. 4 embodiment, chamber 110 may preferably be formed of AETB-8 which is a low-density (8 pounds per cubic foot) composite tile that is made from small diameter (1-3 microns) silica and alumina fibers and larger (8 microns) aluminoborosilicate fibers. In alternate embodiments, bottom insert 210 may be made from various other highly thermal-resistance materials, such as AETB-16, alumina or fused silica. The implementation and use of chamber 110 using top insert 214 is further discussed below in conjunction with FIG. 11.

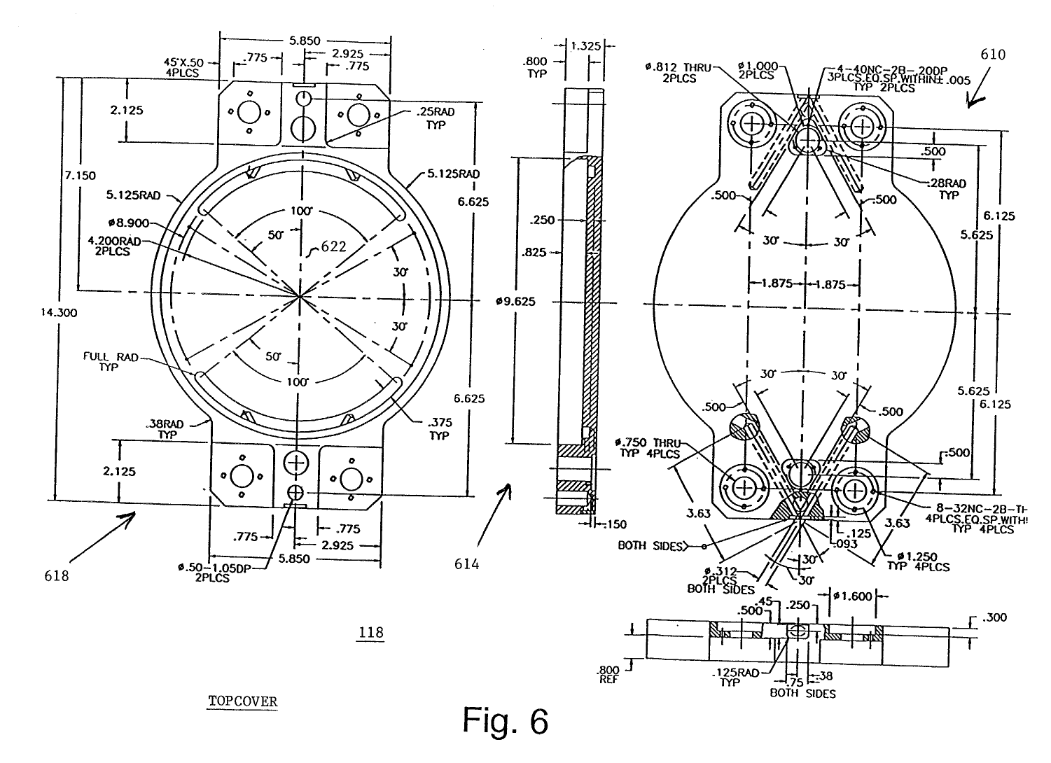

Referring now to FIG. 6, several views for one embodiment of the FIG. 2 top cover 118 are shown, in accordance with the present invention. In the FIG. 6 drawings, measurements are presented in inches unless the drawings indicate to the contrary. In alternate embodiments, top cover 118 may readily include various other elements and configurations in addition to, or instead of, those elements and configurations discussed in conjunction with the FIG. 6 embodiment.

In the FIG. 6 embodiment, view 610 illustrates an exterior plan view of top cover 118, including two gasflow holes, two pneumatic cylinders, and a guide bearing at both the top and the bottom of top cover 118. View 618 of the FIG. 6 embodiment shows an interior plan view of top cover 118 with two pneumatic cylinders and a guide bearing show on both the top and the bottom of top cover 118. In addition, in view 618, two gasflow holes that emerge into a gasflow channel are shown at both the top and the bottom of top cover 118. View 614 shows a cross-sectional view of top cover 118 taken along vertical axis 622 of view 618. View 3614 also shows an internal diameter of top cover 118 (that is sized to receive top insert 214) as being equal to 9.625 inches.

In the FIG. 6 embodiment, top cover 118 may be made of any appropriate material that provides suitable structural support for other elements of chamber 110. For example, in certain embodiments, top cover 118 may be formed of nickel-plated aluminum. The implementation of chamber 110 using top cover 118 is further discussed below in conjunction with FIG. 11.

Referring now to FIG. 7, a plan view for one embodiment of the FIG. 2 heater 218 is shown, in accordance with the present invention. In alternate embodiments of the present invention, heater 218 may readily be implemented to include various other configurations, and may also include various elements and components that are different from those discussed in conjunction with the FIG. 7 embodiment.

Heater 218 may be implemented in any appropriate manner that results in relatively low thermal capacity characteristics to limit absorbing and retaining heat energy. In the FIG. 7 embodiment, heater 218 may preferably be implemented as an approximately circular disk that has a thickness that is approximately the same or less than the thickness of semiconductor wafers 226 that are processed in chamber 110. In the FIG. 7 embodiment, heater 218 may preferably include any suitable heater substrate 718 that provides support for heating elements of heater 218 while maintaining a low thermal capacity. For example, in the FIG. 7 embodiment, heater substrate 718 may be formed of alumina, stainless steel or any other effective material.

Heater 218 may preferably also include a plurality of heater contacts 710. In the FIG. 7 embodiment, heater 218 preferably includes heater contacts 710(a) and 710(b) that may be attached to an appropriate electrical power source. The foregoing heater contacts 710 may then preferably be connected to respective portions of one or more heating elements 714 that may be deposited on heater substrate 718 using any appropriate techniques. In the FIG. 7 embodiment, heating element 714 may preferably be deposited on heater substrate 718 by utilizing a thick film technology to deposit a thick film circuit that generates heat energy when electrical power is applied. The implementation of chamber 110 using heater 218 is further discussed below in conjunction with FIG. 11.

Referring now to FIG. 8, a horizontal cross-sectional view for one embodiment of the FIG. 1 chamber 110 is shown, in accordance with the present invention. The FIG. 8 embodiment illustrates one configuration for efficiently removing heat energy from interior region 234 (see FIG. 2) of chamber 110 by utilizing a gasflow technique. In alternate embodiments, chamber 110 may readily be implemented using various components and configurations in addition to, or instead of, those discussed in conjunction with the FIG. 8 embodiment.

In the FIG. 8 embodiment, chamber 110 may preferably include an input connector 810 for providing a pressurized gasflow from an appropriate gas source to an input gasflow channel 814 in top cover 118. The gasflow may include any type of gaseous substance. For example, the gasflow may include various types of inert gases such as helium or nitrogen. In the FIG. 8 embodiment, a first channel separation 824(a) and a second channel separation 824(b) separate input gasflow channel 814 from an opposing output gasflow channel 836 in top cover 118.

In the FIG. 8 embodiment, top insert 214 may preferably include a series of gasflow input holes that are each connected to a corresponding gasflow input slot for providing the gasflow from input gasflow channel 814 to interior region 234 of chamber 110. For example, in the FIG. 8 embodiment, a gasflow input hole 818 may provide a gasflow from input gasflow channel 814 through input gasflow slot 822 to interior region 234 to effectively cool wafer 226.

In the FIG. 8 embodiment, chamber 110 may preferably also include an output connector 840 for removing the gasflow from chamber 110 through top cover 118. In the FIG. 8 embodiment, output connector 840 may be connected to a vacuum device to more rapidly remove the gasflow from chamber 110. Alternately, chamber 110 may evacuate the gasflow using only pressure from the gas source at input connector 810 without utilizing a vacuum device.

In the FIG. 8 embodiment, top insert 214 may preferably include a series of gasflow output holes that are each connected to a corresponding gasflow output slot for providing the gasflow from interior region 234 of chamber 110 to the output gasflow channel 836, and then to the output connector 840. For example, in the FIG. 8 embodiment, a gasflow output slot 828 may provide the gasflow from interior region 234 to output gasflow channel 836 through output gasflow hole 832 to effectively cool wafer 226.

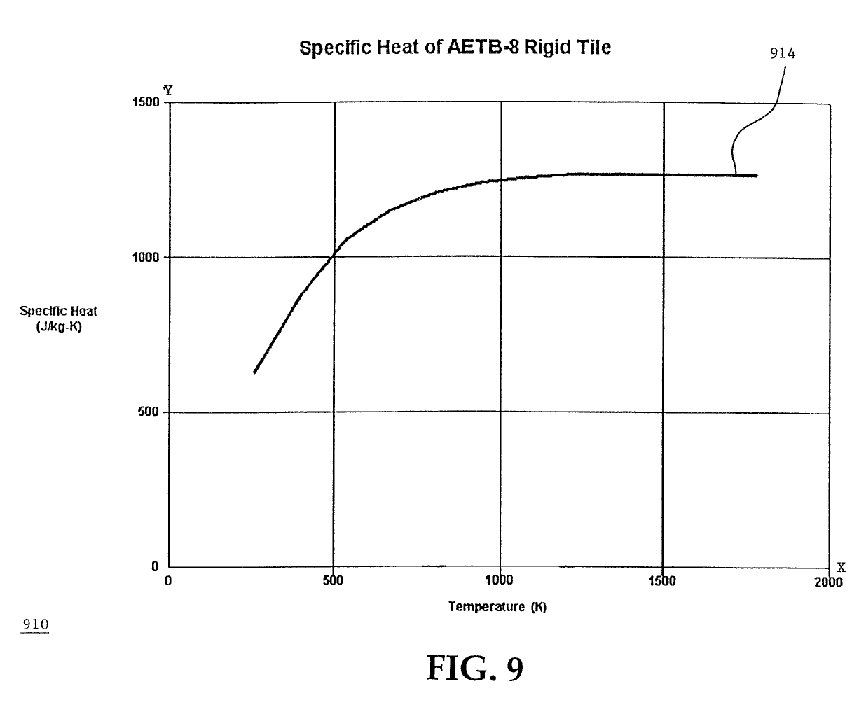

Referring now to FIG. 9, a graph 910 showing thermal capacity characteristics of the FIG. 2 bottom insert 210 and the FIG. 2 top insert 214 is shown, in accordance with one embodiment the present invention. In the FIG. 8 embodiment, graph 910 displays thermal capacity characteristics in terms of specific heat expressed in Joules/(kilograms×degrees Kelvin) on the vertical Y axis, plotted against temperature expressed in degrees Kelvin on the horizontal X axis. In graph 910, the specific values used to produce graph line 914 correspond to bottom inserts 210 and top inserts 214 that are manufactured from AETB-8. However, in alternate embodiments, bottom insert 210 and top insert 214 may be implemented using various other materials with different thermal capacity characteristics.

In accordance with the present invention, chamber 110 may preferably provide a system for performing thermal processing that efficiently exhibits reduced heat energy consumption. In certain embodiments, a value for total heat energy (Qₜₒₜₐₗ) required to perform a heating cycle using chamber 110 may be expressed with the following formula:

Qₜₒₜₐₗ=Q_{wafer}+Q_{walls}+Q_{coating}+Qₕₑₐₜₑᵣ (Equation 1)

where Q_{wafer} equals an amount of heat energy required to heat wafer 226, Q_{walls} equals an amount of heat energy lost in heating walls of interior region 234 of chamber 110, Q_{coating} equals an amount of heat energy lost in heating any coating on the walls of interior region 234, and Qₕₑₐₜₑᵣ equals an amount of heat energy required to heat the heater 218. In certain embodiments in which the walls of interior region 234 have no coating, Equation 1 may omit a value for Q_{coating}.

The present invention's implementation of chamber 110 advantageously minimizes the foregoing Qₜₒₜₐₗ value by minimizing the respective values of Q_{walls}, Q_{coating}, and Qₕₑₐₜₑᵣ. In certain embodiments, values for Q_{wafer}, Q_{walls}, Q_{coating}, and Qₕₑₐₜₑᵣ (expressed in Equation 2 as Qₓ) may each be calculated by utilizing the following formula:

Qₓ=(m) (c) (Δt) (Equation 2)

where m is the mass of a given one of the foregoing components of chamber 110, c is the specific heat of the same given one of the components of chamber 110, and Δt is a temperature differential of the same given one of the components of chamber 110.

In certain embodiments, the foregoing value m (the mass of a given component of chamber 110) may in turn be calculated by utilizing the following formula:

m=(g) (V) (Equation 3)

where g is the specific density of a given one of the foregoing components of chamber 110, and V is the volume of the same given one of the components of chamber 110.

In certain embodiments of chamber 110, wafer 226 may preferably be implemented to have an approximate diameter of 0.2 meters, an approximate thickness of 7×10⁻⁴ meters, an approximate specific density of 2330 kilograms/cubic meter, an approximate thermal conductivity of 125.5 watts/(meters×degrees Kelvin), and an approximate specific heat (thermal capacity) of 700.

In addition, alumina material for the heater 218 and a coating (if any) for the walls of interior region 234 of chamber 110 may preferably have an approximate thickness of 2×10⁻⁴ meters, an approximate specific density of 2330 kilograms/cubic meter, an approximate thermal conductivity of 1.38 watts/(meters×degrees Kelvin), an approximate specific heat (thermal capacity) of 750, and an approximate coefficient of thermal expansion of 7×10⁻⁶ expressed in units of 1/degrees Kelvin.

In certain embodiments that utilize AETB-8 as a thermal insulator, top insert 214 and bottom insert 210 may preferably have walls with an approximate thickness of 0.01 meters, an approximate specific density of 128 kilograms/cubic meter, an approximate thermal conductivity of 0.06 watts/(meters×degrees Kelvin), an approximate specific heat (thermal capacity) of 1200, and an approximate coefficient of thermal expansion of 1×10⁻⁶ expressed in units of 1/degrees Kelvin.

By utilizing Equation 3 and the foregoing values, wafer 226 may be determined to have a mass m that is approximately equal to 0.05 kilograms. Similarly, by utilizing Equation 3 and the foregoing values, the combination of top insert 214 and bottom insert 210 that form the walls of interior region 234 of chamber 110 may be determined to have a mass m that is approximately equal to 0.11 kilograms.

Then, by utilizing Equation 2 and the foregoing values, and assuming that the temperature in interior region 234 is raised from room temperature to approximately 600 degrees centigrade, Q_{wafer} may be determined to approximately equal 1.97×10⁴ Joules, Q_{walls} may be determined to approximately equal 3.71×10⁴ Joules, Q_{coating} may be determined to approximately equal 1.69×10⁴ Joules, and Qₕₑₐₜₑᵣ may be determined to approximately equal 6.04×10³ Joules.

The foregoing results demonstrate that heat energy that is consumed to heat “parasitic” elements such as heater 218, top insert 214, and bottom insert 210 is not excessively high when compared to useful heat energy that is utilized to heat wafer 226. Therefore, in accordance with certain embodiments of the present invention generally, and for an environment in which insulated region 234 is heated from a room temperature to 600 degrees centigrade, Q_{wafer} may approximately equal 2×10⁴ Joules, Q_{walls} may preferably be less than approximately 4×10⁴ Joules, Q_{coating} may preferably be less than approximately 2×10⁴ Joules, and said Qₕₑₐₜₑᵣ may preferably be less than approximately 6×10³ Joules.

This relationship between energy consumed to heat the foregoing parasitic elements and the energy consumed by wafer 226 may be indicated by a Ratio “R” that may be expressed according to the following equation:

R=(Q_{chamber}+Q_{wafer})/Q_{wafer} (Equation 4)

where Q_{chamber} is equal to Q_{walls}+Q_{coating}+Qₕₑₐₜₑᵣ. Based upon the foregoing exemplary values, the combined energy consumed by the parasitic elements of chamber 110 (expressed as Q_{chamber}) may thus be seen to be of the same relative order of magnitude as the energy consumed by wafer 226 (expressed as Q_{wafer}). Using the foregoing exemplary values, R may be calculated to be approximately equal to 4.05. Therefore, in accordance with certain embodiments of the present invention generally, the foregoing ratio R may preferably be less than approximately 4.1.

This advantage translates into low power requirements for operating heater 218. Power requirements (Pₕₑₐₜₑᵣ) for heater 218 may be expressed by the following formula:

Pₕₑₐₜₑᵣ=(R) (m_{wafer}) (Δt) (C_{wafer}) (Equation 5)

where m_{wafer} is the mass of wafer 226, Δt is a temperature change in degrees centigrade per second, C_{wafer} is the thermal capacity of wafer 226, and R is the ratio of (Q_{chamber}+Q_{wafer})/Q_{wafer} from foregoing Equation 4. Therefore, under the foregoing conditions, assuming Δt to be equal to 25 degrees centigrade per second, the energy required for operating heater 218 within chamber 110 may be calculated to be approximately equal to 3.5 kilowatts, which represents a substantial conservation of electrical power when compared to other conventional thermal processing chambers.

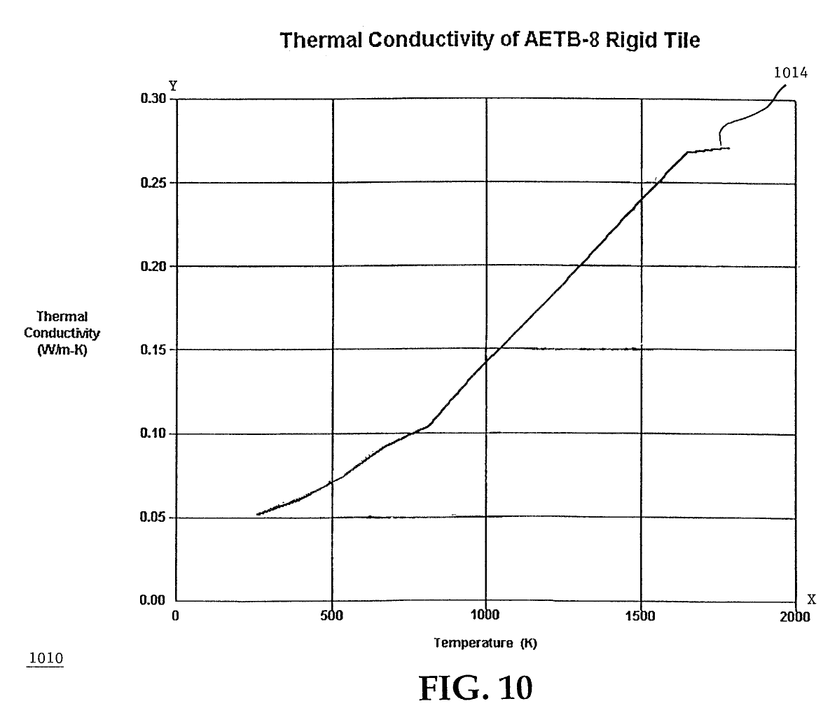

Referring now to FIG. 10, a graph 1010 showing thermal conductivity characteristics of the FIG. 2 bottom insert 210 and the FIG. 2 top insert 214 is shown, in accordance with one embodiment the present invention. In the FIG. 10 embodiment, graph 1010 displays thermal conductivity characteristics in terms of Watts/(meter×degrees Kelvin) on the vertical Y axis, plotted against temperature expressed in degrees Kelvin on the horizontal X axis. In graph 1010, the specific values used to produce graph line 1014 correspond to bottom inserts 210 and top inserts 214 that are manufactured from AETB-8. However, in alternate embodiments, bottom insert 210 and top insert 214 may be implemented using various other materials with different thermal conductivity characteristics. As discussed above in conjunction with FIG. 9, in certain embodiments of chamber 110, heater 218, as well as top insert 214 and bottom insert 210, also exhibit relatively low coefficients of thermal expansion which results in low mechanical stress across chamber 110 during heating and cooling cycles.

Referring now to FIG. 11, a flowchart of method steps for efficiently implementing a thermal processing chamber 110 is shown, in accordance with one embodiment of the present invention. The FIG. 11 example is presented for purposes of illustration, and in alternate embodiments, thermal processing chamber 110 may readily be implemented by utilizing various steps and sequences other than those discussed in conjunction with the FIG. 11 embodiment.

In the FIG. 11 embodiment, in step 1112, a bottom cover 114 may initially be provided, and any appropriate mechanical elements may then preferably be attached to bottom cover 114. For example, mounting brackets, pneumatic cylinders, or guide bearings may be attached to bottom cover 114. Then, in step 1116, a bottom insert 210 that possesses exceptional thermal insulating properties may preferably be provided. A heater 218 with low heat retention characteristics may next be attached to bottom insert 210.

In the FIG. 11 embodiment, in step 1120, the foregoing bottom insert 210 with heater 218 attached may be attached to an interior surface of bottom cover 114. Then, in step 1124, a top cover 118 may be provided, and any appropriate gas supply hardware or fittings such as input connector 810 or output connector 840 (FIG. 8) may then preferably be attached to top cover 118. Then, in step 1128, a top insert 214 that possesses exceptional thermal insulating properties may preferably be provided and attached to top cover 118.

In the FIG. 11 embodiment, in step 1132, the top cover 118 (having top insert 214 attached) may preferably be assembled with bottom cover 114 (having bottom insert 210 and heater 218 attached) to thereby create chamber 110. Finally, in step 1136, any necessary facilities may preferably be attached to chamber 110. For example, electrical power facilities and cooling gas facilities may be attached to chamber 110. The FIG. 11 process may then preferably terminate.

In certain embodiments, the completed chamber 110 may advantageously be combined with other similar chambers to create an array of processing chambers. Chamber 110 is particularly well-suited to such implementations because of the relatively small design of the present invention. Chamber 110 may therefore economically utilize a reduced amount of operating space in a corresponding semiconductor thermal processing facility.

The invention has been explained above with reference to certain embodiments. Other embodiments will be apparent to those skilled in the art in light of this disclosure. For example, the present invention may readily be implemented using configurations and techniques other than those described in the embodiments above. Additionally, the present invention may effectively be used in conjunction with systems other than those described above. Therefore, these and other variations upon the discussed embodiments are intended to be covered by the present invention, which is limited only by the appended claims.

What is claimed is:

1. A system for implementing a thermal processing chamber, comprising:
a bottom insert positioned within a bottom cover, said bottom insert being formed of one or more thermally-insulating materials with optimal heat-resistive characteristics;
a top insert positioned within a top cover, said top insert being formed of said one or more thermally-insulating materials with said optimal heat-resistive characteristics, said bottom insert and said top insert being positionable in a closed position to thereby form an interior insulated region within said thermal processing chamber;
a heater positioned within said interior insulated region of said thermal processing chamber, said heater being formed of one or more heater materials with minimal thermal capacity properties, said heater generating heat energy during a heating cycle, said heat energy being substantially confined within said interior insulated region of said thermal processing chamber; and
a plurality of gasflow holes configured to propagate a gasflow through said interior insulated region of said thermal processing chamber to thereby remove said heat energy during a cooling cycle that follows said heating cycle.

2. The system of claim 1 wherein said thermal processing chamber is utilized for processing a wafer of semiconductor material to thereby produce an electronic device.

3. The system of claim 2 wherein said wafer is supported within said interior insulated region of said thermal processing chamber on a plurality of lift pins that protrude into said interior insulated region.

4. The system of claim 3 wherein said lift pins are adjustable to position said wafer nearer said heater during said heating cycle, and to position said wafer farther away from said heater during said cooling cycle.

5. The system of claim 1 wherein said bottom cover and said top cover are formed of a substantially rigid substance to thereby provide structural support for said thermal processing chamber.

6. The system of claim 5 wherein said bottom cover and said top cover are formed from at least one of aluminum and stainless steel.

7. The system of claim 2 wherein said one or more thermally-insulating materials of said bottom insert and said top insert have a specific heat value at approximately 600 degrees Kelvin that is less than 1500 Joules/(kilograms ×degrees Kelvin).

8. The system of claim 2 wherein said one or more thermally-insulating materials of said bottom insert and said top insert have a thermal conductivity at approximately 600 degrees Kelvin that is less than 1.0 Watt/(meters×degrees Kelvin).

9. The system of claim 2 wherein said one or more thermally-insulating materials of said bottom insert and said top insert have a coefficient of thermal expansion that is approximately equal to 1×10⁻⁶ which is expressed in units of 1/degrees Kelvin.

10. The system of claim 2 wherein said one or more thermally-insulating materials of said bottom insert and said top insert may include at least one of AETB-16, alumina, and fused silica.

11. The system of claim 2 wherein said bottom insert and said top insert are formed of an alumina enhanced thermal barrier material known as AETB-8 which is a low-density composite tile made from small diameter silica fibers, small diameter alumina fibers, and larger diameter aluminoborosilicate fibers.

12. The system of claim 2 wherein said heater is implemented as an approximately circular disk that has a heater thickness that is approximately comparable to a wafer thickness of said wafer, said heater including a heater substrate that provides structural support for heating elements on said heater while maintaining a low thermal capacity, said heater substrate being formed of at least one of alumina, stainless steel and another selected substrate material with said low thermal capacity, said heating elements being deposited on said heater substrate by utilizing a thick film technology to deposit a thick film circuit that generates said heat energy when electrical power is coupled to said heater.

13. The system of claim 2 wherein said one or more heater materials of said heater have a specific heat value at approximately 600 degrees Kelvin that is less than 800 Joules/(kilograms×degrees Kelvin).

14. The system of claim 2 wherein said one or more heater materials of said heater have a thermal conductivity at approximately 600 degrees Kelvin that is less than 1.5 Watts/(meters×degrees Kelvin).

15. The system of claim 2 wherein said one or more heater materials of said heater have a coefficient of thermal expansion that is approximately equal to 7×10⁻⁶ which is expressed in units of 1/degrees Kelvin.

16. The system of claim 2 wherein said thermal processing chamber may be opened to handle said wafer or to facilitate said cooling cycle by moving said top cover away from said bottom cover after injecting pressurized air into a plurality of pneumatic cylinders that connect said top cover to said bottom cover, said top cover responsively riding away from said bottom cover on a plurality of guide bearings that connect said top cover to said bottom cover.

17. The system of claim 2 wherein said gasflow through said interior insulated region includes at least one of nitrogen gas, helium gas, and another selectable inert gas.

18. The system of claim 17 wherein said gasflow is propagated into said thermal processing chamber through an input connector that is connected to a pressurized gasflow source, said gasflow being propagated out of said thermal processing chamber through an output connector that is connected to a vacuum device.

19. The system of claim 18 wherein said gasflow is propagated from said input connector into an input channel in said top cover, said gasflow then being propagated into said interior insulated region through a series of input holes and input slots in said top insert, said gasflow being propagated out of said interior insulated region through a series of output slots and output holes in said top insert to an output channel in said top cover, and then to said output connector.

20. The system of claim 2 wherein said bottom cover includes an approximately cylindrical interior vertical wall that connects along a first lower edge to an approximately circular interior horizontal wall, said bottom insert including an approximately cylindrical external vertical wall that connects along a second lower edge to an approximately circular external horizontal wall, said bottom insert being sized to fit within said bottom cover with said interior vertical wall of said bottom cover being adjacent to said exterior vertical wall of said bottom insert, and said interior horizontal wall of said bottom cover being adjacent to said exterior horizontal wall of said bottom insert.

21. The system of claim 2 wherein said top cover includes an approximately cylindrical interior vertical wall that connects along a first upper edge to an approximately circular interior horizontal wall, said top insert including an approximately cylindrical external vertical wall that connects along a second upper edge to an approximately circular external horizontal wall, said top insert being sized to fit within said top cover with said interior vertical wall of said top cover being adjacent to said exterior vertical wall of said top insert, and said interior horizontal wall of said top cover being adjacent to said exterior horizontal wall of said top insert.

22. The system of claim 2 wherein said top cover with said top insert attached is positioned in contact with said bottom cover said with bottom insert attached to thereby create an approximately cylindrical vacant interior insulated region, a first lower edge of an approximately cylindrical vertical wall of said top cover being positioned adjacent to, and in contact with, a first upper edge of an approximately cylindrical vertical wall of said bottom cover, a second lower edge of an approximately cylindrical vertical wall of said top insert being positioned adjacent to, and in contact with, a second upper edge of an approximately cylindrical vertical wall of said bottom insert.

23. The system of claim 2 wherein said bottom insert includes an approximately cylindrical internal vertical wall that connects along a lower edge to an approximately circular internal horizontal wall, an approximately circular implementation of said heater being positioned adjacent and parallel to said internal horizontal wall of said bottom insert, said wafer then being positioned adjacent and parallel to said heater.

24. The system of claim 2 wherein said thermal processing chamber efficiently exhibits a reduced heat energy consumption in which a total heat energy, Qₜₒₜₐₗ, required to perform a heating cycle may be expressed by a formula:
Qₜₒₜₐₗ=Q_{wafer}+Q_{walls}+Q_{coating}+Qₕₑₐₜₑᵣ
where Q_{wafer} equals an amount of said heat energy required to heat said wafer, Q_{walls} equals an amount of said heat energy lost in heating walls of said interior insulated region, Q_{coating} equals an amount of said heat energy lost in heating any coating on said walls of said interior insulated region, and Qₕₑₐₜₑᵣ equals an amount of said heat energy required to heat said heater.

25. The system of claim 24 wherein said thermal processing chamber minimizes said total heat energy, Qₜₒₜₐₗ, required to perform said heating cycle by minimizing respective values of Q_{walls}, Q_{coating}, and Qₕₑₐₜₑᵣ that may each be calculated by utilizing a formula:
Qₓ=(m) (c) (Δt)
where Qₓ represents any one of Q_{walls}, Q_{coating}, and Qₕₑₐₜₑᵣ, m is a mass of a corresponding one of said walls, said coating, and said heater, c is a specific heat value of said corresponding one of said walls, said coating, and said heater, and Δt is a temperature differential of said corresponding one of said walls, said coating, and said heater.

26. The system of claim 24 wherein said interior insulated region is heated from a room temperature to 600 degrees centigrade, and wherein said Q_{wafer} approximately equals 2×10⁴ Joules, said Q_{walls} less than approximately 4×10⁴ Joules, said Q_{coating} less than approximately 2×10⁴ Joules, and said Qₕₑₐₜₑᵣ is less than approximately 6×10³ Joules.

27. The system of claim 24 wherein wasted heat energy that is consumed to heat parasitic elements such as said heater, said top insert, and said bottom insert is of a comparable order of magnitude when compared to productive heat energy that is utilized to heat said wafer.

28. The system of claim 27 wherein a relationship between said wasted heat energy and said productive heat energy is expressed by a ratio R that may be calculated according to an equation:
R=(Q_{chamber}+Q_{wafer})/Q_{wafer}
where Q_{chamber} is equal to Q_{walls}+Q_{coating}+Qₕₑₐₜₑᵣ, and said ratio R less than approximately 4.1.

29. The system of claim 2 wherein said thermal processing chamber is configured for thermally insulating said interior insulated region to facilitate rapidly performing said heating cycle and said cooling cycle to thereby improve production speeds and semiconductor product characteristics, while simultaneously consuming a minimal amount of said heat energy.

30. The system of claim 2 wherein said thermal processing chamber is utilized in a processing system that includes a plurality of similar thermal processing chambers which are combined into a chamber array, said processing system economically occupying a minimized production space in a corresponding manufacturing facility due to reduced physical dimensions of said plurality of similar thermal processing chambers.

31. A method for implementing a thermal processing chamber, comprising the steps of:
positioning a bottom insert within a bottom cover, said bottom insert being formed of one or more thermally-insulating materials with optimal heat-resistive characteristics;
positioning a top insert within a top cover, said top insert being formed of said one or more thermally-insulating materials with said optimal heat-resistive characteristics, said bottom insert and said top insert being positionable in a closed position to thereby form an interior insulated region within said thermal processing chamber;
positioning a heater within said interior insulated region of said thermal processing chamber, said heater being formed of one or more heater materials with minimal thermal capacity properties, said heater generating heat energy during a heating cycle, said heat energy being substantially confined within said interior insulated region of said thermal processing chamber; and
configuring a plurality of gasflow holes to propagate a gasflow through said interior insulated region of said thermal processing chamber to thereby remove said heat energy during a cooling cycle that follows said heating cycle.

32. The method of claim 31 wherein said thermal processing chamber is utilized for processing a wafer of semiconductor material to thereby produce an electronic device.

33. The method of claim 32 wherein said wafer is supported within said interior insulated region of said thermal processing chamber on a plurality of lift pins that protrude into said interior insulated region.

34. The method of claim 33 wherein said lift pins are adjustable to position said wafer nearer said heater during said heating cycle, and to position said wafer farther away from said heater during said cooling cycle.

35. The method of claim 31 wherein said bottom cover and said top cover are formed of a substantially rigid substance to thereby provide structural support for said thermal processing chamber.

36. The method of claim 35 wherein said bottom cover and said top cover are formed from at least one of aluminum and stainless steel.

37. The method of claim 32 wherein said one or more thermally-insulating materials of said bottom insert and said top insert have a specific heat value at approximately 600 degrees Kelvin that is less than 1500 Joules/(kilograms ×degrees Kelvin).

38. The method of claim 32 wherein said one or more thermally-insulating materials of said bottom insert and said top insert have a thermal conductivity at approximately 600 degrees Kelvin that is less than 1.0 Watt/(meters×degrees Kelvin).

39. The method of claim 32 wherein said one or more thermally-insulating materials of said bottom insert and said top insert have a coefficient of thermal expansion that is approximately equal to 1×10⁻⁶ which is expressed in units of 1/degrees Kelvin.

40. The method of claim 32 wherein said one or more thermally-insulating materials of said bottom insert and said top insert may include at least one of AETB-16, alumina, and fused silica.

41. The method of claim 32 wherein said bottom insert and said top insert are formed of an alumina enhanced thermal barrier material known as AETB-8 which is a low-density composite tile made from small diameter silica fibers, small diameter alumina fibers, and larger diameter aluminoborosilicate fibers.

42. The method of claim 32 wherein said heater is implemented as an approximately circular disk that has a heater thickness that is approximately comparable to a wafer thickness of said wafer, said heater including a heater substrate that provides structural support for heating elements on said heater while maintaining a low thermal capacity, said heater substrate being formed of at least one of alumina, stainless steel and another selected substrate material with said low thermal capacity, said heating elements being deposited on said heater substrate by utilizing a thick film technology to deposit a thick film circuit that generates said heat energy when electrical power is coupled to said heater.

43. The method of claim 32 wherein said one or more heater materials of said heater have a specific heat value at approximately 600 degrees Kelvin that is less than 800 Joules/(kilograms×degrees Kelvin).

44. The method of claim 32 wherein said one or more heater materials of said heater have a thermal conductivity at approximately 600 degrees Kelvin that is less than 1.5 Watts/(meters×degrees Kelvin).

45. The method of claim 32 wherein said one or more heater materials of said heater have a coefficient of thermal expansion that is approximately equal to 7×10⁻⁶ which is expressed in units of 1/degrees Kelvin.

46. The method of claim 32 wherein said thermal processing chamber may be opened to handle said wafer or to facilitate said cooling cycle by moving said top cover away from said bottom cover after injecting pressurized air into a plurality of pneumatic cylinders that connect said top cover to said bottom cover, said top cover responsively riding away from said bottom cover on a plurality of guide bearings that connect said top cover to said bottom cover.

47. The method of claim 32 wherein said gasflow through said interior insulated region includes at least one of nitrogen gas, helium gas, and another selectable inert gas.

48. The method of claim 47 wherein said gasflow is propagated into said thermal processing chamber through an input connector that is connected to a pressurized gasflow source, said gasflow being propagated out of said thermal processing chamber through an output connector that is connected to a vacuum device.

49. The method of claim 48 wherein said gasflow is propagated from said input connector into an input channel in said top cover, said gasflow then being propagated into said interior insulated region through a series of input holes and input slots in said top insert, said gasflow being propagated out of said interior insulated region through a series of output slots and output holes in said top insert to an output channel in said top cover, and then to said output connector.

50. The method of claim 32 wherein said bottom cover includes an approximately cylindrical interior vertical wall that connects along a first lower edge to an approximately circular interior horizontal wall, said bottom insert including an approximately cylindrical external vertical wall that connects along a second lower edge to an approximately circular external horizontal wall, said bottom insert being sized to fit within said bottom cover with said interior vertical wall of said bottom cover being adjacent to said exterior vertical wall of said bottom insert, and said interior horizontal wall of said bottom cover being adjacent to said exterior horizontal wall of said bottom insert.

51. The method of claim 32 wherein said top cover includes an approximately cylindrical interior vertical wall that connects along a first upper edge to an approximately circular interior horizontal wall, said top insert including an approximately cylindrical external vertical wall that connects along a second upper edge to an approximately circular external horizontal wall, said top insert being sized to fit within said top cover with said interior vertical wall of said top cover being adjacent to said exterior vertical wall of said top insert, and said interior horizontal wall of said top cover being adjacent to said exterior horizontal wall of said top insert.

52. The method of claim 32 wherein said top cover with said top insert attached is positioned in contact with said bottom cover said with bottom insert attached to thereby create an approximately cylindrical vacant interior insulated region, a first lower edge of an approximately cylindrical vertical wall of said top cover being positioned adjacent to, and in contact with, a first upper edge of an approximately cylindrical vertical wall of said bottom cover, a second lower edge of an approximately cylindrical vertical wall of said top insert being positioned adjacent to, and in contact with, a second upper edge of an approximately cylindrical vertical wall of said bottom insert.

53. The method of claim 32 wherein said bottom insert includes an approximately cylindrical internal vertical wall that connects along a lower edge to an approximately circular internal horizontal wall, an approximately circular implementation of said heater being positioned adjacent and parallel to said internal horizontal wall of said bottom insert, said wafer then being positioned adjacent and parallel to said heater.

54. The method of claim 32 wherein said thermal processing chamber efficiently exhibits a reduced heat energy consumption in which a total heat energy, Qₜₒₜₐₗ, required to perform a heating cycle may be expressed by a formula:
QₜₒₜₐₗQ_{wafer}+Q_{walls}+Q_{coating}+Qₕₑₐₜₑᵣ
where Q_{wafer} equals an amount of said heat energy required to heat said wafer, Q_{walls} equals an amount of said heat energy lost in heating walls of said interior insulated region, Q_{coating} equals an amount of said heat energy lost in heating any coating on said walls of said interior insulated region, and Qₕₑₐₜₑᵣ equals an amount of said heat energy required to heat said heater.

55. The method of claim 54 wherein said thermal processing chamber minimizes said total heat energy, Qₜₒₜₐₗ, required to perform said heating cycle by minimizing respective values of Q_{walls}, Q_{coating}, and Qₕₑₐₜₑᵣ that may each be calculated by utilizing a formula:
Qₓ=(m) (c) (Δt)
where Qₓ represents any one of Q_{walls}, Q_{coating}, and Qₕₑₐₜₑᵣ, m is a mass of a corresponding one of said walls, said coating, and said heater, c is a specific heat value of said corresponding one of said walls, said coating, and said heater, and Δt is a temperature differential of said corresponding one of said walls, said coating, and said heater.

56. The method of claim 54 wherein said interior insulated region is heated from a room temperature to 600 degrees centigrade, and wherein said Q_{wafer} approximately equals 2×10⁴ Joules, said Q_{walls} less than approximately 4×10⁴ Joules, said Q_{coating} less than approximately 2×10⁴ Joules, and said Qₕₑₐₜₑᵣ is less than approximately 6×10³ Joules.

57. The method of claim 54 wherein wasted heat energy that is consumed to heat parasitic elements such as said heater, said top insert, and said bottom insert is of a comparable order of magnitude when compared to productive heat energy that is utilized to heat said wafer.

58. The method of claim 57 wherein a relationship between said wasted heat energy and said productive heat energy is expressed by a ratio R that may be calculated according to an equation:
R=(Q_{chamber}+Q_{wafer})/Q_{wafer}
where Q_{chamber} is equal to Q_{walls}+Q_{coating}+Qₕₑₐₜₑᵣ, and said ratio R is less than approximately 4.1.

59. The method of claim 32 wherein said thermal processing chamber is configured for thermally insulating said interior insulated region to facilitate rapidly performing said heating cycle and said cooling cycle to thereby improve production speeds and semiconductor product characteristics, while simultaneously consuming a minimal amount of said heat energy.

60. The method of claim 32 wherein said thermal processing chamber is utilized in a processing system that includes a plurality of similar thermal processing chambers which are combined into a chamber array, said processing system economically occupying a minimized production space in a corresponding manufacturing facility due to reduced physical dimensions of said plurality of similar thermal processing chambers.

61. A system for implementing a thermal processing chamber, comprising:
means for positioning a bottom insert within a bottom cover, said bottom insert being formed of one or more thermally-insulating materials with optimal heat-resistive characteristics;
means for positioning a top insert within a top cover, said top insert being formed of said one or more thermally-insulating materials with said optimal heat-resistive characteristics, said bottom insert and said top insert being positionable in a closed position to thereby form an interior insulated region within said thermal processing chamber;
means for positioning a heater within said interior insulated region of said thermal processing chamber, said heater being formed of one or more heater materials with minimal thermal capacity properties, said heater generating heat energy during a heating cycle, said heat energy being substantially confined within said interior insulated region of said thermal processing chamber; and
means for configuring a plurality of gasflow holes to propagate a gasflow through said interior insulated region of said thermal processing chamber to thereby remove said heat energy during a cooling cycle that follows said heating cycle.

62. A system for performing thermal processing, comprising:
a processing chamber that includes an interior insulated region which is encompassed by one or more thermally-insulating materials with optimal heat-resistive characteristics;
a heater positioned within said interior insulated region, said heater being formed of one or more heater materials with minimal thermal capacity properties, said heater generating heat energy that is substantially confined within said interior insulated region until a gasflow is propagated through said interior insulated region to remove said heat energy.
